(19) United States
(12) Patent Application Publication
(10) Pub. No.: US 2012/0098006 A1
(43) Pub. Date: Apr. 26, 2012

(54) LIGHT EMITTING DIODE PACKAGE WITH PHOTORESIST REFLECTOR AND METHOD OF MANUFACTURING

(75) Inventors: Yung-Chang CHEN, Hsinchu City (TW); Hsin-Hsien WU, Hsinchu City (TW); Fu-Wen LIU, Hsinchu (TW); Hao-Wei KU, Zhudong Township (TW); Hsin-Hung CHEN, Hsinchu City (TW)

(73) Assignee: TAIWAN SEMICONDUCTOR MANUFACTURING COMPANY, LTD., Hsinchu (TW)

(21) Appl. No.: 13/178,108

(22) Filed: Jul. 7, 2011

Related U.S. Application Data
(60) Provisional application No. 61/405,837, filed on Oct. 22, 2010.

(51) Int. Cl. H01L 33/60

(52) U.S. Cl. 257/98; 438/27; 438/28; 257/E33.06

(57) ABSTRACT

Optical emitters are fabricated by forming and shaping photoresist reflectors on a package wafer using lithography processes, and bonding Light-Emitting Diode (LED) dies to the package wafer.

### CROSS-REFERENCE TO RELATED APPLICATIONS

The present application claims priority of U.S. Provisional Patent Application Ser. No. 61/405,837, filed on Oct. 22, 2010, which is incorporated herein by reference in its entirety.

### TECHNICAL FIELD

The present disclosure relates generally to a semiconductor device and a method for making, and more particularly, to a semiconductor lighting emitting diode (LED) package and its making method.

### BACKGROUND

A Light-Emitting Diode (LED), as used herein, is a semiconductor light source for generating light at a specified wavelength or a range of wavelengths. LEDs are traditionally used for indicator lamps, and are increasingly used for displays. An LED emits light when a voltage is applied across a p-n junction formed by oppositely doped compound semiconductor layers. Different wavelengths of light can be generated by varying the bandgaps of the semiconductor layers and by fabricating an active layer within the p-n junction.

Traditionally, LEDs are made by growing a plurality of light-emitting structures on a growth substrate. The light-emitting structures along with the underlying growth substrate are separated into individual LED dies. At some point before or after the separation, electrodes or conductive pads are added to the each of the LED dies to allow the conduction of electricity through the structure. LED dies are then packaged by adding a package substrate, bonding wires, a reflector, phosphor material, and lens to become an optical emitter.

Depending on the application in which the optical emitter is used, a viewing angle may be specified from which a majority of emitted light is to be directed. Generally, a horizontal LED die emits about half of its light from the top and about half from the sides. A reflector on a package substrate is usually packaged with the LED die to redirect the side emissions and improve total light extraction in a direction away from the package substrate. LED packaging then involves combining the LED die with a reflector structure on a package substrate and forming electrical connections to power and control the optical emitter.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart illustrating a method of fabricating an optical emitter according to various embodiments of the present disclosure;

FIGS. 2A to 2H are cross-section illustrations of the optical emitter at various stages of fabrication according to various embodiments of the present disclosure;

FIGS. 3A to 3F are cross-section views that illustrate different photoresist profiles formed by adjusting a focal length according to various embodiments of the present disclosure; and

FIGS. 4A and 4B are a top view and a cross-sectional view of an optical emitter with a Zener diode according to an embodiment of the present disclosure.

### SUMMARY

One aspect of the present disclosure involves a method of fabricating an optical emitter. The method includes applying a layer of photoresist on a silicon wafer, exposing a portion of the layer of photoresist to a light, developing the layer of photoresist to form a specific profile pattern, curing the profile pattern to form a plurality of reflectors, bonding a plurality of Light-Emitting Diode (LED) dies to the silicon wafer, electrically connecting the LED dies and the silicon wafer, and dicing the wafer into a plurality of optical emitters. Varying a focal length during the exposing operation adjusts the reflector profile according to viewing angle specifications.

Another aspect of the present disclosure involves a partially fabricated Light-Emitting Diode (LED) package including a package wafer, electrical connections on the package wafer, and a plurality of patterned photoresist having a thickness of at least 100 microns. The patterned photoresist is highly reflective and angled to redirect LED side emissions toward a direction away from the package wafer.

These and other features of the present disclosure are discussed below with reference to the associated drawings.

### DETAILED DESCRIPTION

It is understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Of course, the description may specifically state whether the features are directly in contact with each other. In addition, the present disclosure may repeat reference numerals and/or letters in the various examples. This repetition is for the purpose of simplicity and clarity and does not in itself dictate a relationship between the various embodiments and/or configurations discussed.

An optical emitter includes an LED die attached to a package substrate and optional phosphor material coating over the LED die or disperse in encapsulant or lens material. The LED die may be electrically connected to circuitry on the package substrate in a number of ways. One connection method involves attaching the growth substrate side of the die to the package substrate, and forming electrode pads that are connected to the p-type semiconductor layer and the n-type semiconductor layer in a light-emitting structure on the die, and then bond wiring from the electrode pads to contact pads on the package substrate. Another connection method involves inverting the LED die and using solder bumps to connect the electrode pads on the light-emitting structure directly to the package substrate. Yet another connection method involves using hybrid connectors. One semiconductor layer, for example the p-type layer, may be wired bonded to the package substrate while the other layer (n-type layer) may be soldered to the package substrate.

An LED die emits light in all directions; however, as a light source, the optical emitter outputs light only on one side. Frequently, the light emitter is specified with a limited viewing angle. For the purposes of this application, the viewing angle is defined as the total angle within which 90% of the total luminous flux may be captured. Because much of the light is emitted in undesirable directions, reflectors are added to redirect such light toward a desirable direction to improve overall light extraction.

The side of the LED closest to the package substrate or the top surface of the package substrate is usually designed to reflect light. With only a top or bottom reflection, a horizontal LED die has a significant light output in the horizontal direction (side emission), which may be about half of all light output. The light output in the horizontal direction includes not only light emitted by the LED in a horizontal direction, but also total internal reflection (TIR) light. TIR is an optical phenomenon that occurs when a ray of light strikes a boundary between two mediums at an angle larger than a particular critical angle with respect to the normal to the surface. At this larger angle, if the refractive index is lower on the other side of the boundary, no light can pass through and all of the light is reflected. The critical angle is the angle of incidence above which the total internal reflection occurs. If the angle of incidence is greater (i.e. the ray is closer to being parallel to the boundary) than the critical angle—the angle of incidence at which light is refracted such that it travels along the boundary—then the light will stop crossing the boundary altogether and instead be totally reflected back internally. TIR occurs in a horizontal die at the boundary of the LED die with a lens, encapsulant, or air.

To redirect this significant side light output so that it is projected within the viewing angle, LED dies are packaged with side reflectors. Side reflectors may be added to the LED package separately as independent reflectors or integrated as a part of the package substrate. Independent reflectors (standalone reflectors) may be large compared to the LED dies. The use of independent reflectors in LED package may require stocking a large variety of reflectors for different LED sizes and applications and may be a significant contributor to manufacturing cost.

More cost-effective reflectors are integrated with the package substrate. The LED die is attached to the reflector package substrate with a die attach adhesive, soldering, or other metal bond. The integrated reflector may be formed of the same material as or different material from the package substrate. The integrated reflector suffers from stocking issues and may not be suitable for wafer level packaging where many LED dies are packaged onto a single package wafer at the same time.

In wafer level packaging of LED dies, many LED dies are packaged onto a single package wafer at the same time. A package wafer may be a silicon wafer, a silicon carbide wafer, or a glass wafer. In wafer level packaging of LED dies, the reflectors may be formed in place on the wafer before or after the LED dies are attached and electrically connected. Methods to form reflectors on a wafer or lead frame may involve mold injection of polyphthalamide (PPA) resin, PPA resin is fairly easy to use and not expensive. Reflective material is mixed in the PPA resin while the resin is in a liquid form. The mixture is then injected into a mold on a package wafer. However, as LED power requirements and package life increases, reflectors made using PPA resin experience increased adhesion and yellowing issues. The yellowing of the PPA resin material results from thermal cycling, moisture, and passage of time. The yellowing reduces the total light output of the LED package because reflectivity decreases, reducing light extraction. Compounded by decreased emission from the LED die and conversion efficiency of the phosphor materials over time, the overall light output by the optical emitter can decrease dramatically. The adhesion issues result from the different coefficients of thermal expansion (CTE) of the PPA resin and underlying package wafer to which it is adhered. As the PPA resin and package wafer cycle thermally, crevices form between the PPA resin and the package wafer and can cause the reflector to delaminate partially or completely from the package wafer.

One alternative to using the PPA resin is using silicone material to mold reflectors on the package wafer using either compression molding techniques or injection molding techniques. A silicone compound, once cured, is more resistant to yellowing and has a better CTE match with the package wafer. However, restrictions on the old frame size limits the number of dies that can be formed per package wafer in wafer level packaging. Because several mold frames are used to form reflectors on one wafer, some wafer surface area between the mold frames cannot be used for packaging. During a compression molding process, many issues can arise to cause the reflector to fail. Not enough molding precursor, an air pocket, or a plugged pathway can cause a reflector to be missing a portion. Compression molding also includes many operations involving different machines. In one example, the process includes a lithography process, stripping process, and compression molding process, each involving a different machine to complete. The added complexity and cost render compression molding less attractive as an option. Injection molding process involves using high pressure to insert the molding precursor and can damage delicate LED and Zener diode dies. Another common issue with molding processes is the cost and difficulty of changing molds. Each reflector design requires new molds to be cast, which may be very expensive and time consuming; thus, a reflector design cannot be easily changed. The molds also wear out and need to be replaced periodically, increasing the overall manufacturing cost of the optical emitter.

An optical emitter in accordance with various embodiments of the present disclosure includes a reflector formed on a package wafer in a wafer level package process using only lithography processes. A number of optical emitters are fabricated by forming photoresist reflectors on a package wafer using lithography processes, bonding Light-Emitting Diode (LED) dies to the package wafer, electrically connecting the LED dies and the package wafer, and dicing the wafer into a number of optical emitters. The reflector may be formed on the package wafer before or after bonding the LED die and may be formed over a Zener diode die bonded to the package wafer.

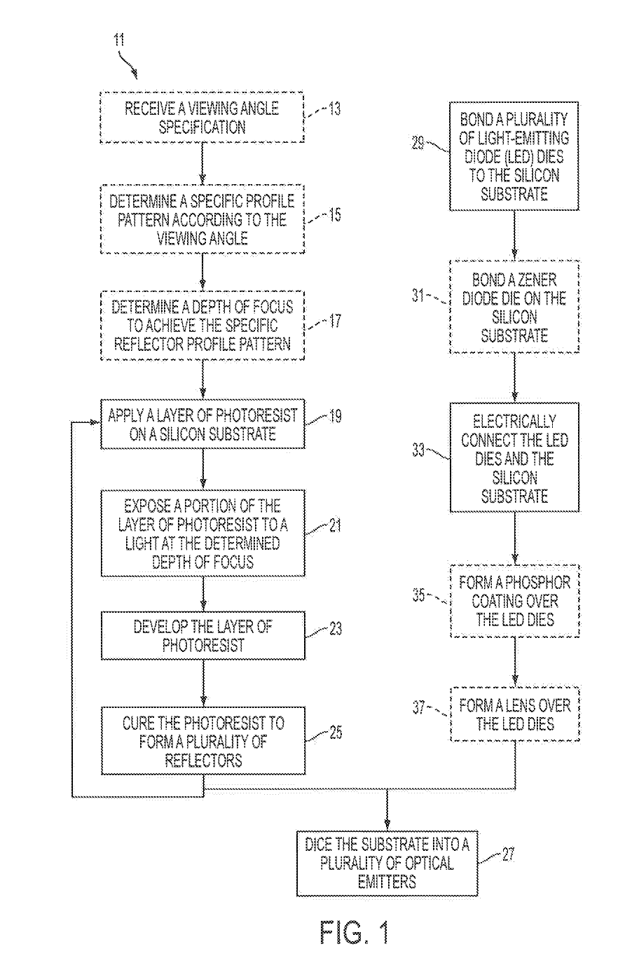

FIG. 1 is a flowchart illustrating a process flow 11 of fabricating an optical emitter using wafer level packaging according to various aspects of the present disclosure. In one aspect, the methods of FIG. 1 pertain to a method of manufacturing an optical emitter including using a photolithographic process to form reflectors. In another aspect, the methods of FIG. 1 pertain to a method of designing and manufacturing an optical emitter according to device specifications, including specifications as to a viewing angle.

In operation 13 of FIG. 1, a viewing angle specification is received. A viewing angle may be specified based on an application of the optical emitter. For example, an optical emitter in a back light unit of an LCD screen would have a smaller viewing angle than an optical emitter in a consumer light bulb or a display panel. Based on the viewing angle specified and the LED die, a specific profile pattern for a reflector is determined in operation 15. The distribution of light output from an LED die can be modeled and a reflector profile pattern can be determined from those achievable using a photolithographic process. A main parameter is the reflector profile angle, which is an angle between the reflector's surface and a normal with respect to the package wafer. This angle is about 45 degrees in some embodiments, in a range of about 15 degrees to about 60 degrees in some other embodiments, and in a wider range in further embodiments. A bigger reflector profile angle means a bigger viewing angle for the optical emitter. The reflector profile is not necessarily linear and can be curved, thus the reflector profile angle can be a range.

A focal length to achieve the determined profile pattern is then determined in operation 17. The focal point, and therefore the focal length, is specified relative to a photoresist layer to be developed to obtain the reflector. The light used in the photolithography exposure process can be focused in the photoresist layer, above it, or below in the package wafer with relative accuracy. The focal length relative to the photoresist layer determines an energy gradient of the radiation the photoresist layer receives. A differing amount of radiation in a top portion of the photoresist layer as opposed to a bottom portion of the photoresist layer can affect the shape and hence the reflector profile formed. Note that the light refracts at the interface between (i) an air or gas or vacuum medium and (ii) a top surface of the photoresist medium because of the refraction index (RI) difference between the two media. This operation takes into account the RI difference between different materials to calculate a focal length/focal point that would generate a focus to achieve the determined profile pattern. As used hereinafter, focusing a light at a particular point (the focal point) includes accounting for RI differences in multiple media/materials, and thus, may result in different focal point, focal length, or focusing than when used in a single medium.

Generally, a photoresist material is sensitive to a light exposure and changes its material property after exposure. A photoresist can be a positive resist or a negative resist. A positive resist is a type of photoresist in which the portion of the photoresist that is exposed to light becomes soluble to the photoresist developer. The portion of the photoresist that is unexposed remains insoluble to the photoresist developer. A negative resist is a type of photoresist in which the portion of the photoresist that is exposed to light becomes insoluble to the photoresist developer. The unexposed portion of the photoresist is dissolved by the photoresist developer.

Many types of photoresist materials are used in industry for various applications. The selection depends, among others, on the size of the patterns, subsequent processing conditions, and permissible stripping conditions based on properties of the underlying layers. The photoresist may include a photoacid generator (PAG) that can be decomposed to form acid during a lithography exposure process (providing the dissolution switch), a thermal-acid generator which can generate more acid during a subsequent baking process, and a cross-linker which can induce cross-linking reaction during the subsequent baking process.

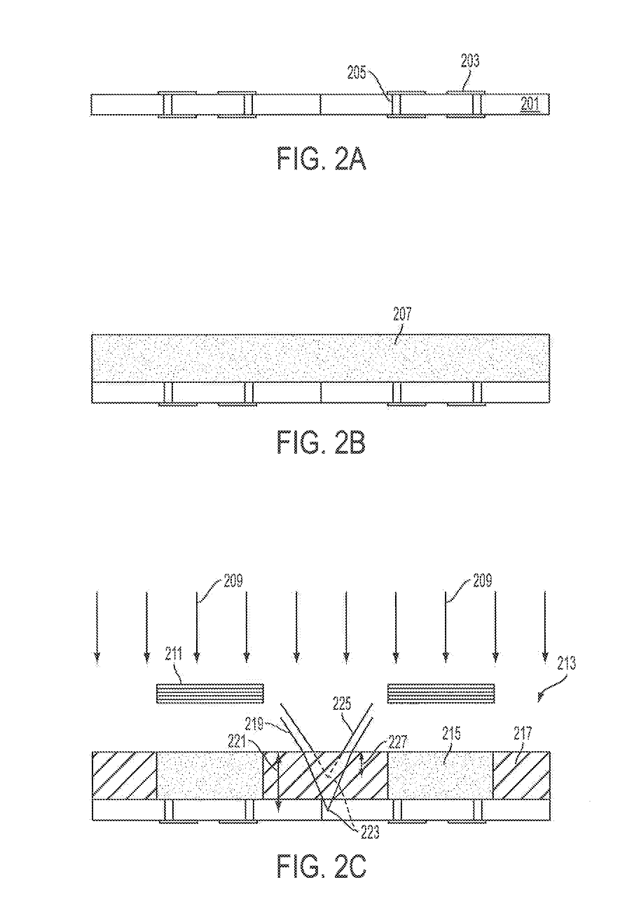

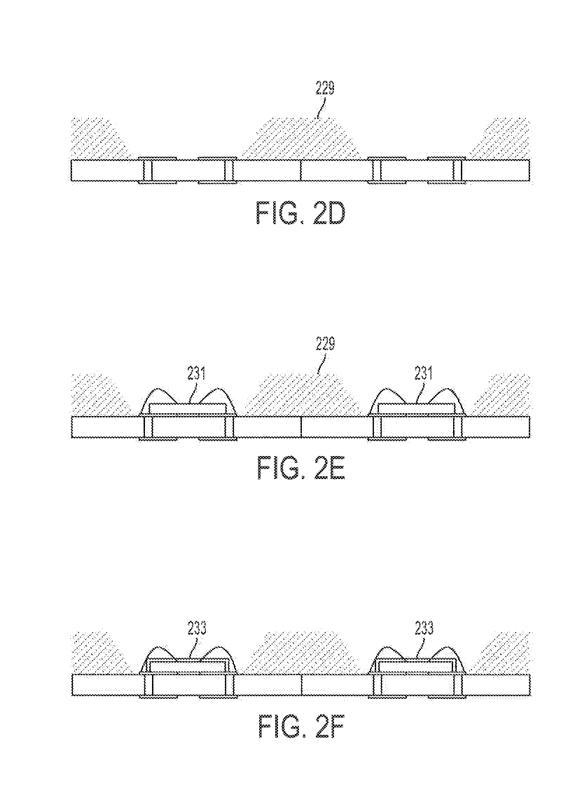

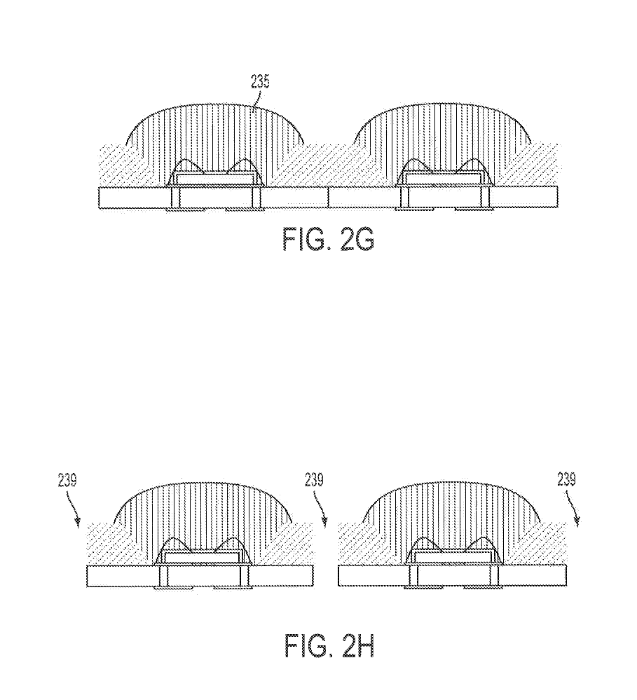

A common type of photoresist material is epoxy based negative photoresist. Negative photoresists generally adhere very well to wafers used as packaging wafers, such as silicon. Epoxy based photoresists can be made to have very high viscosities so as to form very thick layers of up to 2 mm. Referring back to FIG. 1, a photoresist layer is formed on the package wafer, for example, a silicon wafer, in operation 19. An example packaging wafer 201 is shown in FIG. 2A. The packaging wafer 201 includes metal pads 203 and through substrate vias 205. Metal pads 203 and through substrate vias 205 are used on packaging wafers in wafer level packaging to conduct electricity and/or heat. Though not necessary for the embodiments described in this disclosure, the use of metal pads and through substrate vias on a silicon wafer improves thermal and electrical conductivities.

The photoresist layer may be applied using typical spin-coating processes to ensure a uniform layer; however, for thick coats above 100 microns of very viscous photoresist, other coating processes may be used. For example, a printing method may be used to uniformly coat a layer of photoresist. Using the printing method, a stencil with a desired coating area cut out may be overlaid on the package wafer, then photoresist material may be dispensed on the package wafer or a flat part of the stencil. One or more blades or wipers may brush across the stencil back and forth to apply the photoresist in the cut out portion in a uniform manner. The thickness of the stencil corresponds to the thickness of the desired photoresist coating. In a first example, the stencil is a metal sheet having a cut-out portion in the shape of the package wafer centering above a package wafer, with the edges covering an edge of the package wafer. The package wafer edge covered by the stencil may be about 1 mm to about 5 mm, typically around 2 mm. In a second example, the stencil is a metal sheet having a plurality of cutout portions corresponding to the locations of individual dies on the package wafer, e.g., in a pattern of many rectangles. In a third example, the single cut-out portion has edges corresponding to the perimeters of the pattern of dies on the package wafer. While the cut-out portion of the third example is similar to the first example in that only one-cut covers the entire package wafer, individual die areas are not marked. In the third example, the cutout is only the edge portion of the second example. The package wafer edge covered would vary depending on the location on the package wafer.

FIG. 2B illustrates a packaging wafer 201 with a photoresist layer 207. The photoresist layer 207 is at least 100 microns thick and may be at least about 300 microns thick or up to 2 mm thick. The photoresist material suitable for the embodiments of the present disclosure is highly reflective. The reflectivity may be obtained by including a metal oxide or other additives having a white color, such as titanium oxide, aluminum oxide, zirconium oxide, or combination of these and other additives. Commercially available photoresist material may be modified to change one or more material properties in accordance with various embodiments of the present disclosure. For example, white coloring may be added to clear photoresist or viscosities may be increased by adding a resin. In order to coat a thick photoresist layer 207 using spin coating methods, a photoresist material of a high viscosity of at least several thousand centipoises (cp), for example, 10,000 cp, may be used. In one example, a photoresist material having a viscosity of more than 50,000 cp, or about 60,000 to 70,000 cp is used to form a 300 micron photoresist layer. Note that such high viscosity is not required for coating photoresist material using printing methods because the stencil can contain the photoresist material until at least after a soft bake process, when the photoresist material would no longer flow. Suitable photoresist materials include T75W15A/F87FW15B white inks available from Teamchem Company of Taiwan or Focus Coat DPR-55FW from Asahi Chemical of Japan.

Referring back to FIG. 1, in operation 21, a portion of the photoresist layer is exposed to a radiation or light at the determined focal length. FIG. 2C illustrates this operation. Light/radiation 209 is directed through a photomask having masked portions 211 and transparent/gap portions 213. The light passes through the transparent portions/gaps 213 and is stopped by the masks 211. The light that passes through the gaps 213 reaches the photoresist layer 207 and causes a change in a material property of at least one photo sensitive component in the photoresist layer, depending on whether the photoresist is a negative or a positive resist. As illustrated in FIG. 2C, the photoresist layer 207 is a negative photoresist, so that the unexposed portions 215 of the photoresist layer will be soluble in the developer and the exposed portions 217 will be indissoluble in the developer.

A stepper is used to expose the photoresist. The image on a photomask is reduced by a lens, focused and projected onto the surface of a package wafer coated with photoresist. When the wafer is processed in the stepper, the pattern on the photomask (which may contain one or a number of individual chip patterns) is exposed repeatedly across the surface of the wafer in a grid. The stepper steps the wafer from one shot location to another. This is accomplished by moving the wafer back and forth and left and right under the lens of the stepper. Steppers are capable of high resolution because only a limited area is exposed each time.

Referring to FIG. 2C, several possible different light paths, e.g., 219 and 225 are shown. Light path 219 is focused at 223 below the photoresist layer with a subject focal length 221 as measured from the top of the photoresist 207. Note that the light refracts at the interface between the air or gas or vacuum medium and the top surface of the photoresist medium because of the refraction index (RI) difference between the two media. When the light is focused (223) past the photoresist, the light may refract once more if the package wafer RI is different from the photoresist RI.

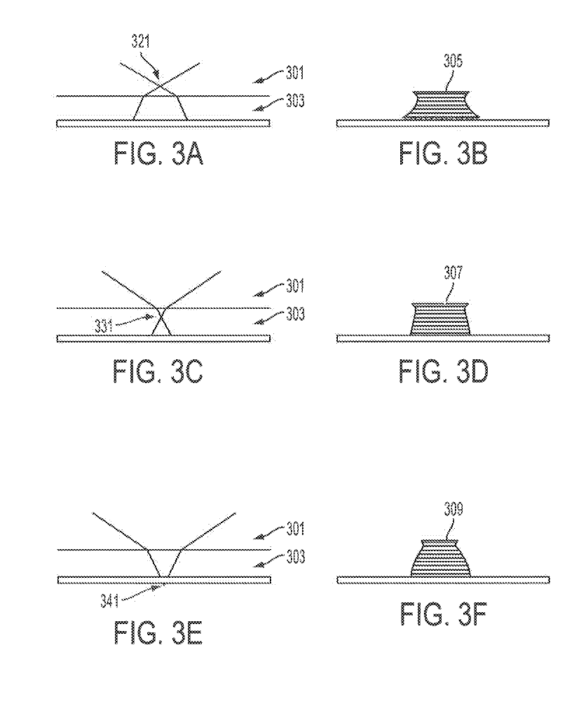

Light path 225 is focused at 223 within the photoresist layer with a subject focal length 227, also measured from the top of the photoresist 207. The location of the focal points 223 affects how much light energy material at different depths of the photoresist receive during the exposure operation. FIG. 3 illustrates examples of various focal points and their effects on the resist shape after developing and baking.

FIGS. 3A and 3B illustrate a shallow focal point 321 above the photoresist layer 303. As shown, the focal point 321 is in the medium 301 (air, gas or vacuum) above the photoresist. FIG. 3B shows the resulting photoresist 305, with a curved profile with decreasing slope toward the bottom of the photoresist.

FIGS. 3C and 3D illustrate a focal point 331 within the photoresist layer 303. The energy distribution at different photoresist depths is relatively uniform. FIG. 31) shows a resulting photoresist profile 307 that is approaching vertical. With further fine-tuning the profile can be made substantially vertical.

FIGS. 3E and 3F illustrate a focal point 341 beyond the photoresist layer 303. Depending on whether the package wafer reflects the light used in photolithography, the resulting photoresist profile 309 may have a sloped and less curved shape than photoresist profile 305 of FIG. 3B.

FIGS. 3B, 3D, and 3F show that by adjusting the focal length, photoresist material, and optionally other photolithographic parameters, a particular photoresist profile with a specific slope or even curvature can be achieved. Note that the profiles and focal length shown in FIGS. 3A to 3F are merely examples and are not meant to be inclusive of all possibilities. By tuning various parameters and using different photoresist materials, many reflector profiles may be obtained. For example, one parameter is the thermal processing of the resist. The photoresist may be baked, heated to an elevated temperature for a time, after exposure to amplify the chemical reaction initiated by the light exposure, and the subsequent baking may further change the photoresist profile.

Referring to FIG. 1, in operation 23 the layer of photoresist is developed. The development process involves exposing the photoresist to a developer, e.g., a liquid such as TMAH (tetra-methyl ammonium hydroxide). Depending on whether the photoresist is a negative or a positive resist, either the exposed or unexposed portion would dissolve in the developer, leaving a desired photoresist pattern behind. The remaining photoresist may be cured in operation 25 to form a plurality of reflectors 229 as shown in FIG. 2D.

For larger LEDs a larger reflector may be formed by using multiple layers of photoresist in a stacking formation. Operations 19-25 are repeated in some embodiments to increase the size of the reflector formed by forming another reflector portion on top of a reflector portion already formed. For example, a first reflector may be formed having a thickness of about 200 microns and a subsequent layer may be formed over the first reflector having a thickness of about 100 micron to form a larger reflector with a thickness of about 300 microns. In some embodiments, a second/upper photoresist is filled in the inner space of the first/lower reflector and, then, second radiating/developing processes are performed to remove the second/upper photoresist from both (i) the inner space of the first/lower reflector and (ii) the inner space of the second/upper reflector.

One or more of the operations 29 to 35 may be performed before or after forming the reflectors in operations 19 to 25. FIGS. 2E to 2H show an embodiment where these operations are performed after forming the reflectors. According to operation 29 of FIG. 1, a number of light-emitting diode (LED) dies are bonded to the silicon wafer. An LED die includes a light emitting structure (not shown) on a growth wafer and one or more electrode pads for electrically connecting to a package wafer. The light-emitting structure has two doped layers and a multiple quantum well layer between the doped layers. The doped layers are oppositely doped semiconductor layers. In some embodiments, a first doped layer includes an n-type gallium nitride material, and the second doped layer includes a p-type material. In other embodiments, the first doped layer includes a p-type gallium nitride material, and the second doped layer includes an n-type gallium nitride material. The MQW layer includes alternating (or periodic) layers of active material, for example, gallium nitride and indium gallium nitride. For example, in one embodiment, the MQW layer includes ten layers of gallium nitride and ten layers of indium gallium nitride, where an indium gallium nitride layer is formed on a gallium nitride layer, and another gallium nitride layer is formed on the indium gallium nitride layer, and so on and so forth.

The doped layers and the MQW layer are all formed by epitaxial growth processes. After the completion of the epitaxial growth processes, a p-n junction (or a p-n diode) is essentially formed. When an electrical voltage is applied between the doped layers, an electrical current flows through the light-emitting structure, and the MQW layer emits light. The color of the light emitted by the MQW layer is associated with the wavelength of the emitted radiation, which may be tuned by varying the composition and structure of the materials that make up the MQW layer. The light-emitting structure may optionally include additional layers such as a buffer layer between the substrate and the first doped layer, a reflective layer, and an ohmic contact layer. A suitable buffer layer may be made of an undoped material of the first doped layer or other similar material. A light-reflecting (reflective) layer may be a metal, such as aluminum, copper, titanium, silver, silver, alloys of these, or combinations thereof. An ohmic contact layer may be an indium tin oxide (ITO) layer. The light reflecting and ohmic contact layers may be formed by a physical vapor deposition (PVD) process or a chemical vapor deposition (CVD) or other deposition processes.

The LED dies may be attached to the package wafer in a number of ways. In certain embodiments where the growth substrate side of the LED die is attached to the package wafer, the attachment may be performed by simply gluing the LED die using any suitable conductive or non-conductive glue, depending on whether the side of the LED die and the package wafer to be attached are conductive and whether isolation is required. In embodiments where the LED die side opposite of the growth substrate is attached to the package wafer, the attachment may include electrically connecting the LED die by bonding the electrode pads on the LED to contact pads on the package wafer. This bonding may involve soldering or other metal bonding. In some embodiments, the growth substrate is removed and one side of the LED die is bonded and electrically connected to the wafer, in this case the attaching may be accomplished using metal bonding such as eutectic bonding.

In one example, the LED dies are attached to the die by soldering. To bond the LED die by soldering, a solder is printed on the package wafer and reflowed while contacting the LED die. In another example, the LED dies are attached are glued to the wafer using a thermally conductive glue.

In an optional operation 31, a Zener diode die is also bonded on the package wafer, A Zener diode die is commonly used as an electro-static discharge (FSD) and/or electrical fast transient (EFT) protection circuit. Other commonly used ESD and EFT protection devices include a transient suppression diode and a multilayer varistor. The Zener diode is known to absorb light and thus decrease light extraction and output. In certain embodiments of the present disclosure, the Zener diode is bonded onto the package wafer and the reflector is formed over it. Located under a portion of the reflector, the Zener diode would be outside of the optic system because it is not exposed to the light emission from the LED die directly.

In operation 33, the LED dies and the package wafer, which may be a silicon wafer, is electrically connected. At least two electrical connections are made per LED die, one each to the p-type and n-type doped layers. In some cases, two electrical connections are made to the p-type layer for current spreading purposes. As discussed, the electrical connection may involve wire bonding, soldering, metal bonding, or a combination of these to electrical connection pads on the package wafer. If the LED dies are soldered onto the package wafer, the soldering forms one electrical connection and only one electrical connection remains per die, from the topside of the LED dies, e.g., the p-junction, to the wafer. If the LED dies are glued to the wafer, then two or more electrical connections may be necessary to separately connect the p-junction and the n-junction to terminals on the package wafer. FIG. 2E shows electrical connections between the LED dies 231 attached to a package wafer. Because the electrical connection may take a variety of forms, the structure shown in FIG. 2E is illustrative only—the electrical connections need not be two wire bonds.

Referring to FIG. 1, a phosphor coating is formed in some embodiments over the LED dies in operation 35. Many LED applications requires a color mixture output, such as white light as a mixture of either blue and yellow or red, green, and blue. In LED applications where the light output is a mixture, one or more phosphor material is added to convert at least a portion of the light emitted to another wavelength. In some embodiments, the phosphor coating is dispensed or sprayed onto a surface of the LED die in a concentrated viscous fluid medium, such as glue, and dried or cured in place. FIG. 2F shows LED dies with a phosphor coating 233. The phosphor coating 233 may conformally cover the LED die 231 so that when a current is passed through the LED die 231, the light emitted by the LED die is transmitted through the phosphor material 233. In other embodiments, phosphor material is added to other elements of the optical emitter, for example, the lens. The phosphor material converts a portion of the light emitted by the LED to a different wavelength and allows a portion of the light to pass through. The combination of the passed through light and the converted light is perceived. Although a white light is generated this way, the concepts may be used to generate light of any color.

In operation 37 of FIG. 1, a lens is formed over each of the LED dies. FIG. 2G shows the LED package with lens 235. In one example, the lens 235 is molded over each LED die. The lens molding may be performed by placing a lens mold over the package wafer and the LED dies, inserting a lens precursor material in each lens mold cavity, curing the lens precursor material, and then removing the lens mold. One lens mold having many lens mold cavities may be used for the package wafer, or several lens molds may be used at the same time on the package wafer. The package wafer may include alignment marks between individual LED dies to ensure that the mold cavities are placed accurately over the LED die. In another example, a predetermined amount of lens precursor material is dispensed into the reflector cavity and a rounded surface is formed by surface tension.

The lens may be formed in many shapes. While FIG. 20 shows a rounded (convex) top surface, the top surface may have other shapes, including a flat surface or a concave surface. In some embodiments, the lens is not attached to the reflector and is a portion of an ellipsoid formed over each of the LED dies. Other lens shapes may be used to affect the angular light output depending on final LED application.

At this point, the package wafer includes a number of optical emitters. According to some embodiments, the number of optical emitters packaged on a package wafer may be sold and shipped as is, with final processing to incorporate the optical emitter in a light application apparatus performed elsewhere.

In other embodiments, the optical emitters are separated from each other and further processing may be performed before shipping. Referring back to FIG. 1, in operation 27 the package wafer is diced into a number of separate LEI) packages. As shown in FIG. 211 at 239, the dicing may be performed through the photoresist-formed reflector to separate the optical emitters. In other embodiments, the reflectors of each optical emitter may be formed separately from each other so that the dicing is performed through the package wafer only. Further processing may include encapsulating, adding external leads/wires, and final binning.

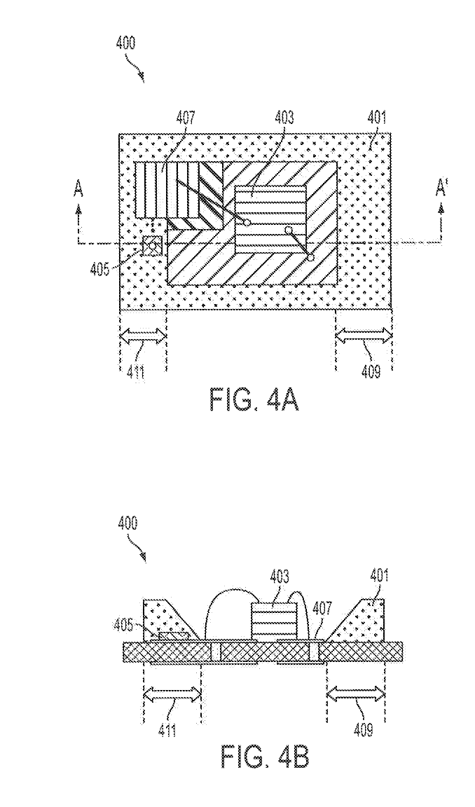

One particular feature of the various embodiments of the present disclosure pertains to the ability to define a reflector having any size or shaped area or profile. The ability to define a reflector having any size or area is illustrated in FIGS. 4A and 4B showing an embodiment of an optical emitter 400 with an embedded Zener diode 405. FIG. 4A is a top plan view of the optical emitter 400 while FIG. 4B is a cross section view taken along line A-A′ of FIG. 4A. As discussed in association with operation 31 of FIG. 1, a Zener diode 405 may be included in the optical emitter under the reflector 401. The Zener diode 405 is marked by dotted lines in FIG. 4A and shown under the reflector in FIG. 4B. Note that the dotted line portion of metal pad 407, which corresponds to metal pad 203 in FIG. 2A, is also located under reflector 401.

The reflector 401 area surrounds the LED die 403 and portions of the metal pad 407, and has widths 409 and 411 on two sides. The widths 409 and 411 can be increased or decreased merely by adjusting the photomask exposure areas. For example, width 411 may be increased to be larger than width 409 to accommodate a larger Zener diode die 405. Additionally, the reflector need not have a rectangular base. For example, the base may be an ellipse or another polygon. The sloped interior of the lens may also be an ellipse or a polygon, such as a rectangle as shown in FIG. 4A.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. It is understood, however, that these advantages are not meant to be limiting, and that other embodiments may offer other advantages. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of wafer level packaging optical emitters, said method comprising:
applying a layer of photoresist having reflectivity on a wafer;
exposing a portion of the layer of photoresist to light, then developing and curing the layer of photoresist to form a plurality of reflectors having a specific profile pattern; and
bonding a plurality of Light-Emitting Diode (LED) dies to the wafer in correspondence with the reflectors.

2. The method of claim 1, wherein said exposing comprises:
exposing the portion of the layer of photoresist to the light through a photomask, wherein the light is focused toward the layer of photoresist.

3. The method of claim 1, further comprising:
forming a lens over each of the plurality of LED dies.

4. The method of claim 1, wherein said bonding of the plurality of LED dies is performed before said applying the layer of photoresist.

5. The method of claim 1, wherein the layer of photoresist is at least 100 microns thick.

6. The method of claim 1, further comprising
electrically connecting the LED dies and the wafer.

7. The method of claim 1, wherein the specific profile pattern forms an angle up to 60 degrees with a normal of the wafer.

8. The method of claim 1, wherein the specific profile pattern is a curve.

9. The method of claim 1, wherein said applying the layer of photoresist on the wafer comprises spin-coating or printing.

10. The method of claim 9, wherein said printing comprises spreading dispensed photoresist across a stencil over the wafer.

11. The method of claim 1, wherein the photoresist has a viscosity greater than 10,000 cp.

12. The method of claim 1, further comprising
bonding an electronic element to the wafer before said applying the layer of photoresist so that the electronic element is buried under the subsequently formed reflectors.

13. The method of claim 1, wherein the photoresist is epoxy based.

14. The method of claim 1, further comprising bonding a Zener diode die on the wafer.

15. The method of claim 1, further comprising
dicing the wafer between the LED dies through the reflectors and the wafer or through the wafer only.

16. The method of claim 1, further comprising:
repeating said applying, exposing, developing, and curing to formed multiple reflectors one on top another.

17. A method of manufacturing reflectors for optical emitters in a wafer level packaging process, said method comprising:
receiving a viewing angle specification of optical emitters to be wafer level packaged;
applying a layer of photoresist having reflectivity on a wafer;
determining a specific profile pattern of reflectors to be manufactured according to the viewing angle specification;
determining a focal length of a focused radiation to achieve the specific profile pattern; and
performing a lithography process, using the focused radiation at the determined focal length, on the layer of photoresist to form a plurality of reflectors having the specific profile pattern.

18. The method of claim 17, wherein, during said performing the lithography process, the radiation is focused at the determined focal length to a focal point within or beyond the layer of photoresist.

19. A partially fabricated Light-Emitting Diode (LED) package, comprising:
a package wafer;
electrical connections on the package wafer; and
a plurality of patterned reflective photoresist having a thickness of at least 100 microns,
wherein the patterned photoresist is angled to redirect LED side emissions away from the package wafer.

20. The partially fabricated LED package, wherein the patterned photoresist has a curved profile.
